(19) United States
(12) Patent Application Publication
(10) Pub. No.: US 2003/0111439 A1
(43) Pub. Date: Jun. 19, 2003

(54) Method of forming tapered electrodes for electronic devices

(76) Inventors: Linus Albert Fetter, Morganville, NJ (US); Ken Matthew Takahashi, Warren, NJ (US)

Correspondence Address: HARNESS, DICKEY & PIERCE, P.L.C., P.O. BOX 8910, RESTON, VA, 20195, US

(21) Appl. No.: 10/021,881

(22) Filed: Dec. 14, 2001

(51) Int. Cl. H01L 21/461; H01B 13/00

(52) U.S. Cl. 216/13; 438/978; 438/713

(57) ABSTRACT

In the method, a substrate is coated with different films to be patterned. These films have different etch rates. The films and substrate are then coated with a primary etch mask, and subsequently patterned to produce an electrode that has a gradual taper at the electrode edge. The formed electrode eliminates any abrupt substrate to electrode step, so that any subsequent thin-film deposition of piezoelectric material is continuous over the entire electrode surface and the electrode/substrate interface.

### BACKGROUND OF THE INVENTION

1. Field of the Invention

The present invention generally relates to the fabrication of electronic devices and more particularly to a method and system for tapering the sidewall angle of an etched thin film that is part of the formed electronic device.

2. Description of Related Art

Conventionally, electronic devices are made through thin-film depositions, each followed by or combined with one or more processing steps. As a specific example, a thin film resonator (TFR) typically is comprised of a piezoelectric material interposed between two conductive electrodes, one of which can be formed on a solid support structure or thin membrane.

As a specific example, for 2 GHz applications, a 25,000 Angstroms-thick piezoelectric film is deposited over a 2,000 Angstroms-thick patterned base electrode, which provides electrical connectivity between resonators. The piezoelectric material is typically AlN, but may also be formed of ZnO or CdS amongst other piezoelectric materials. The electrodes are formed from a conductive material, preferably of Al, but may be formed from other conductors as well. These films are deposited and lithographically patterned into their useful form in much the same way modern integrated circuits are made.

As just described, the piezoelectric film typically extends across the edges of the patterned base electrode. However, the deposition of this film across the patterned metal edge often results in cracking of the piezoelectric film along this metal edge.

This discontinuity is due in part to the fabrication process. As previously noted, the piezoelectric is typically deposited on the patterned conducting electrode. The electrode patterning process necessarily creates a near vertical step between a substrate surface on which the electrode is patterned and the electrode surface. Accordingly, subsequent deposition of the piezoelectric film results in film fracturing wherever the piezoelectric film covers the electrode edges at the step between electrode and substrate.

This discontinuous or fractured piezoelectric film thus deposited may lead to electrical discontinuities. These discontinuities will render these devices useless, and in the case of devices on membranes, the TFR device could literally fall apart. Therefore, what is needed is a method to improve device integrity by fabricating the device so that these discontinuities are not present.

### SUMMARY OF THE INVENTION

The present invention provides a method for producing thin-film-based electronic devices in which patterned films may be formed with tapered edges. The degree of taper is determined and controlled chemically; that is, by the chemical composition of an etch bath used in patterning the films.

In the method, a substrate is coated with different films, each of which are to be patterned. The films have different, pre-measured etch rates in a pre-determined etching solution. These films and substrate are then coated with a primary etch mask, and subsequently etched to produce an patterned film that has a gradual taper at the patterned edge. This patterned film may be part of an electrode formed by the process. This eliminates an abrupt substrate to electrode step, so that subsequent deposition of an overlying material is continuous over the entire electrode surface and the electrode/substrate interface.

The taper is produced by controlling the relative etch rates of the deposited films and achieved by selection of the proper components of their common etch bath. Specifically, the etch rate of a film which is adjacent to the primary etch mask, is controlled so as to be some multiple of the etch rate of another lower film beneath the film adjacent to the primary etch mask. This film may thus act as a sacrificial film, or “disappearing” mask layer for the film that is disposed beneath the sacrificial film, gradually exposing the lower film to the etchant so as to induce the taper.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings, wherein like elements are represented by like reference numerals, which are given by way of illustration only and thus are not limitative of the present invention and wherein:

FIG. 1 illustrates a process of forming an electrode for an electronic or acoustic device in accordance with the invention;

FIG. 2 illustrates the steps in forming a thin-film resonator device in accordance with the invention;

FIGS. 3(a) and 3(b) illustrate how different taper angles are obtained based on etch rate differentials in accordance with the invention;

FIGS. 4(a) through 4(e) are cross-sectional views illustrating the evolution of the tapered edge in accordance with the method of the invention; and

FIG. 5 illustrates a cross-section of an exemplary electronic device with tapered electrodes in accordance with the invention.

### DETAILED DESCRIPTION

The method described below may be applied to any electronic device fabrication process where an abrupt discontinuity in surface topology is undesirable. Where appropriate, the inventors describe the fabrication of a thin film resonator (TFR) as a specific example.

The method of the present invention ensures a smooth topological transition between electrode and substrate when producing electronic devices. In the method, thin films having different rates, where at least one of the films represents a component of the electrode, are applied on a substrate. The components are selected so as to have differing etch rates in a common, pre-selected etch bath. These films and substrate are then coated with a primary etch mask, and subsequently patterned (etched) in a chemical bath to produce the patterned electrode. The electrode thus formed has a gradual taper at the electrode edge. This eliminates the abrupt substrate to electrode step, so that subsequent deposition of piezoelectric material provides a continuous film over the entire electrode surface and the electrode/substrate interface.

The taper is produced by controlling the relative etch rates between one film that is adjacent to the primary etch mask and on top of another film. Etch-rate control is achieved by adjusting the chemical composition of the etch bath. The film adjacent the etch mask has a faster etch rate than the film beneath it. It thus acts as a sacrificial film, or a “disappearing” mask layer for the second film beneath it, gradually exposing the lower, slower-etching second film to the etchant so as to induce the taper. Both films may or may not be made of metal. Accordingly, the present invention provides a method whereby a film is patterned with tapered edges; step-induced defects in an overlaying layer, such as a piezoelectric layer are thus eliminated.

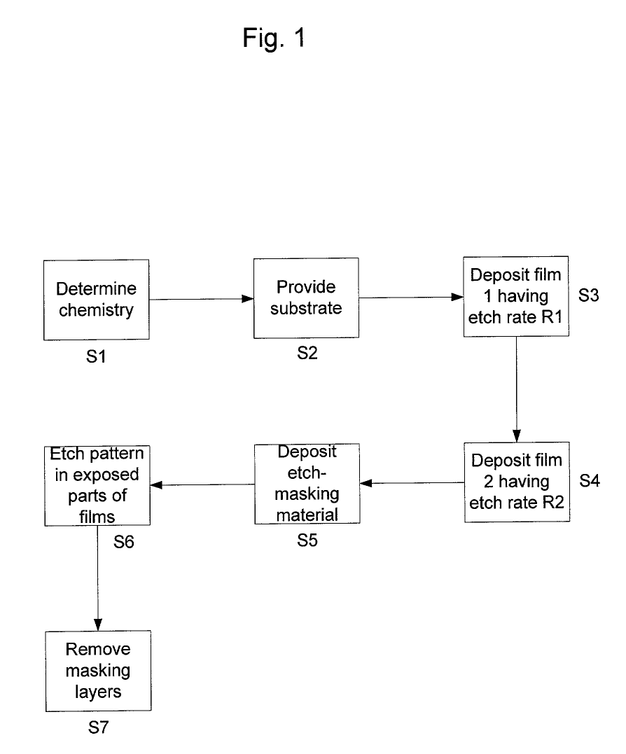

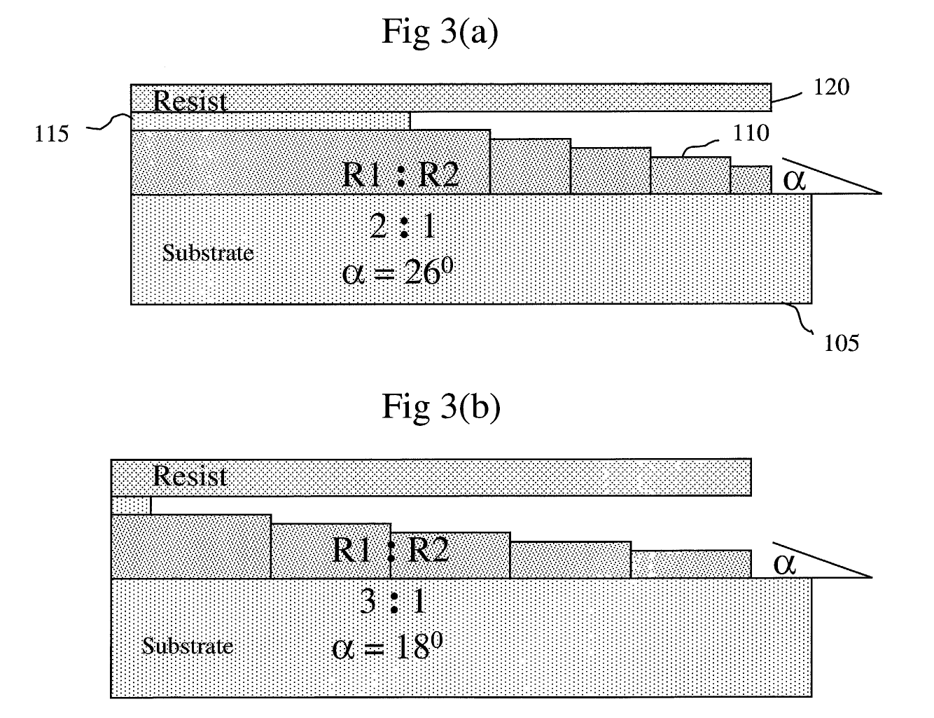

FIG. 1 illustrates a process of forming an electrode for an electronic or acoustic device in accordance with the invention. Prior to forming the electrode, the composition type of the chemical bath should be determined (Step S1). The bath's components may be defined theoretically and/or experimentally, and should be characterized by differential etch rates of the materials employed so that the bath's etch rate on the first, upper film (see for example film 115 in FIGS. 3(a) and 3(b)) is faster than its etch rate on the adjacent second film (see for example film 110 in FIGS. 3(a) and 3(b)).

In a preferred embodiment, a titanium/aluminum metal stack of materials could be used under a pattern-defining layer (see for example film 120 in FIGS. 3(a) and 3(b)) to form the base electrode of an electronic device or acoustic device such as a TFR. The etchant used to pattern the electrode could be a mixture of phosphoric, acetic, and hydrofloric acids, for example, which etches Ti faster than it etches Al.

Next, a base support structure such as a substrate is provided (Step S2). The base structure may be a silicon wafer substrate, and, in the case of a TFR, preferably may be coated with a plurality of alternating acoustic reflecting layers of acoustically mismatched materials such as SiO₂ and AIN, which are mounted on a solid substrate such as a silicon, quartz, or glass wafer. Alternatively, the substrate may be a membrane which is fabricated by removal of the material beneath it. In this embodiment, the substrate is a Si substrate which has been coated with layers of silicon dioxide (SiO₂) and poly-silicon.

After providing the substrate, a thin metal film layer approximately 100 nanometers (or 100×10⁻⁹ meters) thick is deposited on the substrate surface (Step S3). The metal film may be the bottom surface electrode which is common to series and shunt TFR components (not shown) and is preferably composed of Al, but other conductors may be used as well. This deposition may preferably be performed in a vacuum chamber using one of a variety of thin-film deposition techniques which are known in the art, such as RF sputtering, DC sputtering of a metallic target, electron beam deposition, etc.

Particularly, this film has a desired or specified etch rate R2 in the selected bath that will be used to pattern-etch the electrode. As noted, the film may be spin-coated, vacuum deposited, plated, etc or applied using any of a variety of thin-film deposition techniques known in the art. In a preferred embodiment, the inventors have used physical vapor deposition (PVD), a vacuum-based technique, to deposit a metal film such as Al on the substrate.

In the next step, another film having an etch rate RI in the selected bath is deposited (Step S4) on the film layer formed in Step (S3). To assure a suitable taper, R1 will be greater than R2. Preferably this second layer is a thin titanium (Ti) film, although neither of the two films are required to be metal and could also be formed of non-metal materials.

Once the two films have been deposited, they undergo a patterning process. A lithographic process may be employed in which a thin layer of a photo-sensitive, chemically-resistant polymer, or “photo resist”, is applied to completely coat the films (Step S5). Exposure to light through a “photo mask”, a material or masking layer that has holes or openings at certain locations for light to pass, sensitizes the photo resist such that subsequent immersion in a developer removes only that resist material that was subject to the light. At this point, the sample surface consists of regions where the protective resist layer remains, and regions of un-protected metal.

Accordingly in Step S5, the substrate and films are coated with a mask material; defined within this material is the appropriate pattern. Photo-resist is the material most often used for this step, and this is true in the inventors' process as well. Standard resist processing techniques as above are employed, although variations may be used to help determine the final film profile. Such a treatment would inhibit resist adhesion during the etch, enhancing the etch of the top film and thereby increasing the taper.

The patterning process continues with the transfer of a lithographically-defined pattern into the metal layers via an etching process (Step S6). This process is carried out in the chemical bath determined in Step S1. Specifically, the process used to remove metal is a wet-chemical etching process. This process, through chemical action, removes any metal which is left unprotected by the photo resist, while leaving the resist-coated metal largely intact, thereby “sculpting” the metallic surface into the desired electrode pattern. Alternatively instead of wet-chemical etching, certain combinations of gasses could be used for this patterning process.

When the remaining etch mask material (photo resist) is removed by a solvent (Step S7), a metallic layer such as an electrode, which is defined by the desired pattern, remains. Alternatively, if the desired surface is to be that of the bottom metal, the remaining top metal layer could be removed by selective etching. In either case, the tapered electrode remains, because the relatively rapid removal of the upper Ti film causes its etch front to progress at a higher rate than the etch front in the underlying Al film. The upper film thus acts as a “disappearing mask”, resulting in a taper in the Al metal film edge.

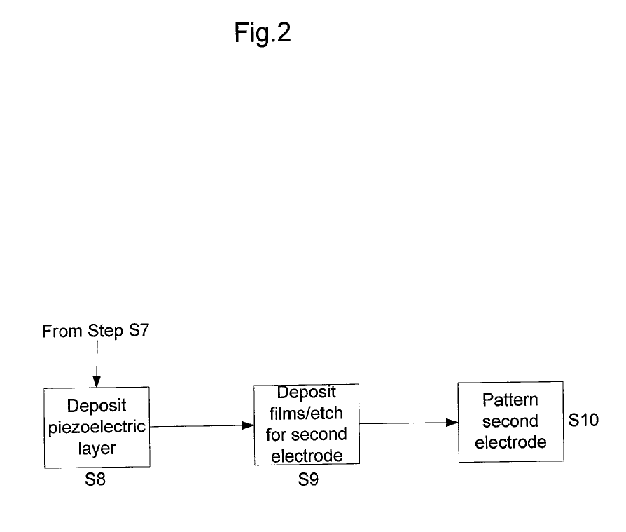

FIG. 2 illustrates the remaining steps in forming a thin-film resonator device in accordance with the invention. The semi-completed device is then returned to the vacuum chamber for the deposition of an active piezoelectric material layer (Step S8). Similar to the metal deposition alternatives listed above, the piezoelectric layer can be deposited in different ways, such as through RF sputtering of an insulating target, pulsed DC reactive sputtering of a metallic target, chemical vapor deposition (CVD) and molecular beam epitaxy (MBE) for example. The material is grown so that it is evenly deposited on top of the bottom electrode and substrate. Moreover, there is no discontinuity at a junction with the electrode and substrate, because of the tapered edges formed due to the differing etch rates of the two films comprising the electrode.

Finally, the piezoelectric may be coated with a second set of thin metal film layers Al and Ti, which will form the top electrode of the TFR component (Step S9). This electrode layer may be formed exactly as the first electrode was formed in FIG. 1, with the films patterned and etched (Step S10) using the chemical etching process described above. Once the photo resist is removed, the resultant structure is that of a TFR device, which could be incorporated into a TFR-based RF filter for example.

FIGS. 3(a) and 3(b) illustrate how different taper angles are obtained based on etch rate differentials in accordance with the invention. On top of a substrate 105, there is deposited a first film 110, a second film 115 and then the etching mask (photo resist 120). The taper angle is controlled by the etch bath composition, which is a combination of chemicals such that etch rate R1 (the etch rate of film 115) is greater than etch rate R2 (the etch rate of the film 110). Shown in FIGS. 3(a) and 3(b) are the edge-taper angles obtained for a relative etch ratio of 2:1 (α=26°, where etch rate R1 is twice as fast as R2), and for a higher ratio of 3:1 (α=18°).

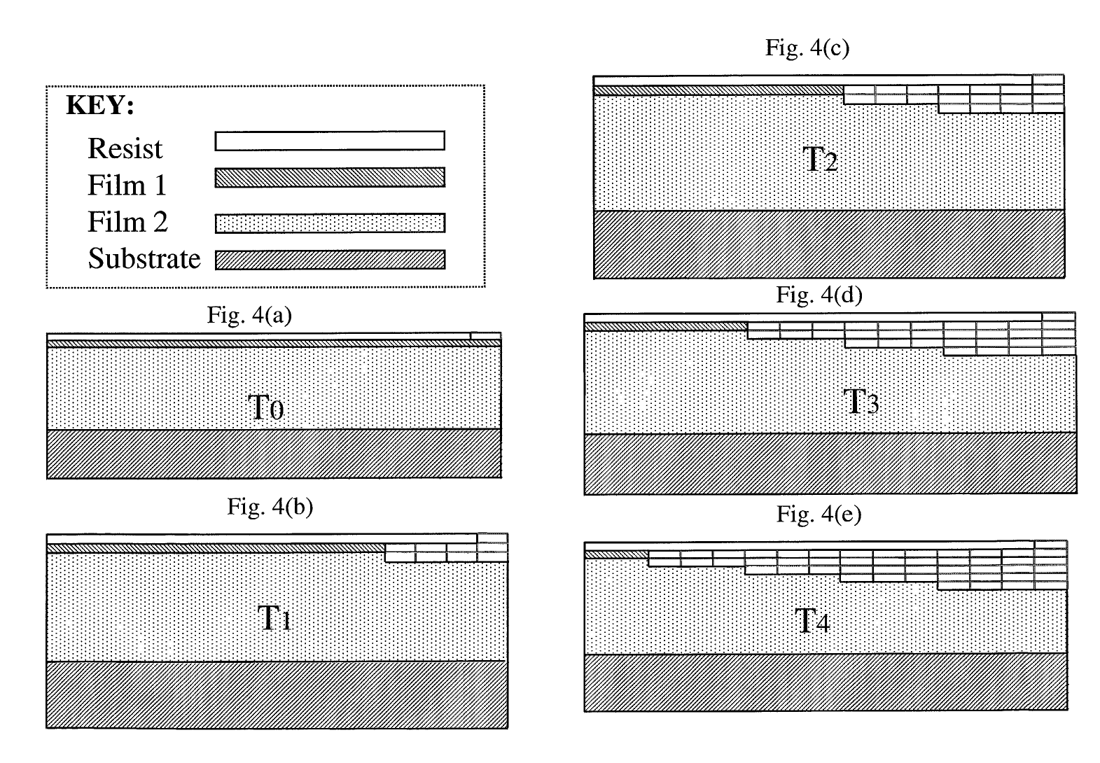

FIGS. 4(a) through 4(e) are cross-sectional views illustrating the evolution of the tapered edge in accordance with the method of the invention. In FIGS. 4(a)-4(e) there is an inset key to assist in identifying the various films. FIG. 4(a) illustrates a sample with only the resist patterned, before etching has begun (To). Once etching begins, the Ti layer (Film 1) is more quickly eaten away by the etchant (hence disappearing mask layer) than is the Al film (Film 2). As the patterning process progresses through times T₁ to T₄, the etch front in the Ti layer (Film 1) continues its relatively rapid progress, progressively exposing more Al surface of Film 2 to the etchant and thus causing a slope or taper to be formed during patterning. The slope of this taper may be controlled by adjusting etch bath components and/or etch ratios, a flatter slope being obtained with a higher relative etch ratio between Film 1 and Film 2.

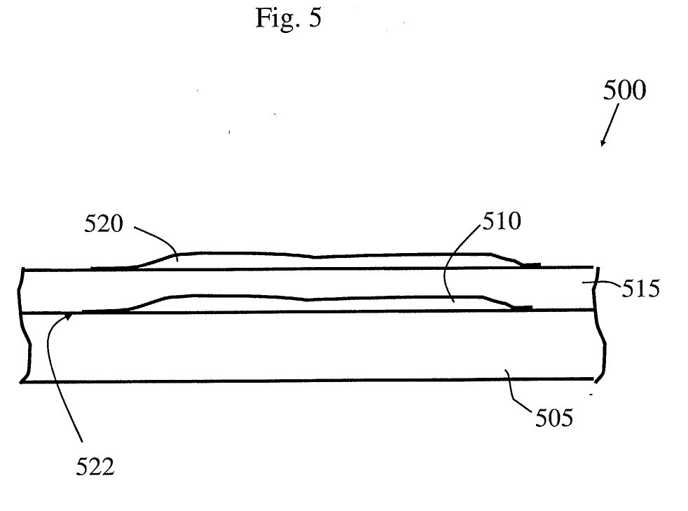

FIG. 5 illustrates a cross-section of an exemplary electronic device with tapered electrodes in accordance with the invention. As shown in FIG. 5, electronic device 500 includes a substrate 505, bottom electrode 510, piezoelectric film 515 and top electrode 520. The junction where the edge of bottom electrode meets substrate 505 is smooth, and the piezoelectric film 515 is continuous over this electrode/substrate junction due to the formation of the tapered edges 522, as described above in accordance with the invention. Accordingly, the electronic device 500 is not subject to the possibility of a discontinuous or fractured piezoelectric film that renders conventional devices useless.

The invention being thus described, it will be obvious that the same may be varied in many ways. Although the process has been described with respect to TFR devices, this technique may also be applied to other technologies involving aluminum metallization, or other metallization schemes. Such variations are not to be regarded as departure from the spirit and scope of the invention, and all such modifications as would be obvious to one skilled in the art are intended to be included within the scope of the following claims.

What is claimed is:

1. A method of forming a film with a tapered edge in an electronic device, comprising:
providing a substrate;
forming a first film on the substrate;
forming a second film on the first film, the first film having an etch rate that is different from an etch rate of the second film;
forming an etching mask on said second film; and
etching the first and second films using the etching mask to form a resultant film having a tapered edge.

2. The method of claim 1, wherein the second film is a disappearing mask layer for the first film, gradually exposing the first film to an etchant so as to induce a tapered edge which slopes to the substrate.

3. The method of claim 2, further comprising depositing at least one overlaying layer on the first film, the tapered edge ensuring that said at least one overlaying layer is continuous at a junction of the first film with the substrate.

4. The method of claim 1, wherein said first film includes Al and said second film includes Ti.

5. The method of claim 1, wherein the etch rate of said second film is faster than the etch rate of said first film.

6. The method of claim 2, wherein the angle of taper is controlled based on the relative etches rates of the first and second films.

7. The method of claim 1, wherein said resultant film after etching is the remaining first film, said first film being a formed bottom electrode of the electronic device.

8. A method of forming a electronic device, comprising:
(a) providing a substrate;
(b) forming a first film on the substrate;
(c) forming a second film on the first film, the first film having an etch rate that is different from an etch rate of the second film, the first and second films to be used to form a bottom electrode of the electronic device;
(d) forming an etching mask on said second film;
(e) etching the first and second films using the etching mask to form the electrode with a tapered edge;
(f) depositing a overlaying material on the formed electrode; and
(g) forming a top electrode on said overlaying material by repeating steps (a) to (e).

9. The method of claim 8, wherein the second film is a disappearing mask layer for the first film, gradually exposing the first film to an etchant so as to induce a tapered edge which slopes to the substrate.

10. The method of claim 8, wherein said tapered edge ensures that the overlaying layer and any subsequent layers deposited thereon are continuous at a junction of the electrode with the substrate.

11. The method of claim 8, wherein said first film includes Al and said second film includes Ti.

12. The method of claim 8, wherein the etch rate of said second film is faster than the etch rate of said first film.

13. The method of claim 9, wherein the angle of taper is controlled based on the relative etches rates of the first and second films.

14. The method of claim 8, wherein the overlaying layer is composed of piezoelectric.
